(19) United States
(12) Patent Application Publication
(10) Pub. No.: US 2003/0190822 A1
(43) Pub. Date: Oct. 9, 2003

(54) Charged particle beam adjusting method, pattern transfer method and device manufacturing method using the same method

(76) Inventor: Mamoru Nakasuji, Yokohama-shi (JP)

Correspondence Address: Mamoru Nakasuji, 2-15-11, Serigaya-chou, Kounan-ku, Yokohamashi, Kanagawa-ken, JP

(21) Appl. No.: 09/818,227

(22) Filed: Mar. 28, 2001

(30) Foreign Application Priority Data
Mar. 31, 2000 (JP) 2000-135250

(51) Int. Cl. H01L 21/324

(52) U.S. Cl. 438/795

(57) ABSTRACT

Problem: In a pattern size measurement apparatus, there are difference between pattern size measured around the optical axis and that measured at deflection edge.

In a defect detection apparatus, the defects that are between raster and around the optical axis may be missed to detect.

In an electron beam pattern transfer apparatus, there are pattern size difference between patters formed around the optical axis and that formed at the deflection edge.

Means for Resolution:

In the pattern size measuring apparatus or the defect detection apparatus, the beam size is adjusted so that everywhere in the deflection field the beam diameter is constant, and then lens excitation is adjusted under focus condition at around the optical axis.

In the electron beam pattern transfer apparatus, for the sub field around the optical axis the lens excitation is adjusted so under focus condition that the beam blur at the sub-field around the optical axis is nearly equal to that at the sub field in the deflection edge. As a results pattern size accuracy can be improved.

### FIELD OF THE INVENTION

This invention pertains to a charged particle beam adjusting method, in which a finely focused charged particle beam is scanned on a specimen surface and a defect detection or a critical dimension measurement are done. This invention also pertains to a high precision pattern transfer method, in which a fine pattern on a reticle is projected on a radiation sensitive substrate by charged particle beam. This method is suitable, in particular, for forming a fine and high density pattern as fine as 100 nm or bellow, with high throughput.

This invention also pertains to a device manufacturing method using the defect detection method, the critical dimension measurement and the pattern transfer method.

### BACKGROUND OF THE INVENTION

There has been put a defect detection apparatus and a critical dimension measurement apparatus to practical use, in which a finely focused charged particle beam is scanned on a specimen surface, where a dynamic focus lens is adjusted as shown in FIG. 4 so that a minimum beam diameter is obtained everywhere in scan position.

There has been proposed a charged particle beam pattern transfer method wherein a pattern formed on the reticle has been divided into plural main fields, each main field has been divided into many sub fields, and a pattern transfer has been done sub field by sub field. Therein lens conditions in each sub field has been adjusted so that the maximum beam blur in the sub field have become minimum and for that lens condition, pattern transfer has been done.

For the conventional beam adjusting method, the beam diameter around the optical axis is much smaller than that at the field edge, and as a results, the critical dimension measurement accuracy is no good, and defect detection probability is different between at the optical axis and at the field edge.

Moreover, for the conventional pattern transfer method, the beam blur at the sub field around the optical axis is much smaller than that at the sub field on the main field edge, as a result, there are transfer pattern size difference between around optical axis and around the main field edge. Especially the pattern size difference is large when a mask bias or a process bias is adopted.

### SUMMARY OF THE INVENTION

It is a purpose of the invention to provide a charged particle beam adjusting method, in which a high precision pattern size measurement can be done and a high reliable detect detection can be done.

It is an another purpose of the invention to provide a pattern transfer method, in which a good critical dimension can be obtained everywhere in the chip. It is a final purpose of the invention to provide a device manufacturing method, in which a high yield can be obtained.

The charged particle beam adjusting method of the first embodiment of this invention comprises the step of:

(a) a charged particle beam source, condenser lens, deflector, an objective lens and a specimen are arranged,

(b) lens conditions that a beam diameter is minimum at the deflection edge are searched,

(c) the beam diameter is memorized,

(d) the lens conditions are defined so that in all the deflection field the beam diameter is nearly equal to that memorized in (c).

The charged particle beam adjusting method of the second embodiment of this invention comprises the step of:

(a) a charged particle beam source, a deflector, an objective lens and a specimen are arranged,

(b) a lens condition that a beam resolution is the best at the deflection field edge is searched,

(c) the beam resolution value is memorized,

(d) the lens condition is defined so that in all the deflection field the beam resolution value is nearly equal to that memorized in (c).

The pattern transferring method of the third embodiment of this invention comprises the step of:

(a) chip pattern are divided into plural main fields,

(b) each main field is divided into plural sub-fields,

(c) the minimum value for the maximum beam blur in the sub-field where is the sub-field in the main field edge, is searched through the dynamic focus lens change, and the minimum value is memorized;

(d) the lens conditions for the other sub-fields are defined so that the maximum beam blur in each sub-field is equal to or larger than the said memorized beam blur in (c),

(e) the pattern transfer is done using the defined condition in (d), wherein the pattern transfer is done sub-field by sub-field.

### BRIEF DESCRIPTION OF THE DRAWINGS

FIG. 1 is a typical charged particle beam adjusting method of this invention.

FIG. 2 is a typical charged particle beam pattern transfer method of this invention.

FIG. 3 is a concrete beam adjusting method for the pattern transfer method of this invention.

FIG. 4 is a conventional beam adjusting method.

FIG. 5 is a flow chart for a device manufacturing method of this invention.

### DETAILED DESCRIPTION OF A PREFERED EMBODIMENT

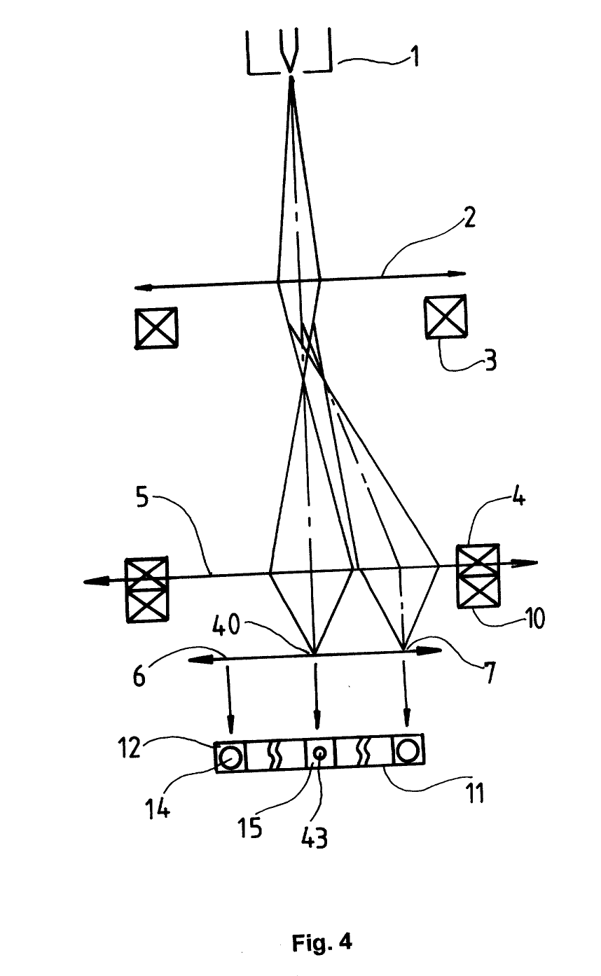

The following are explanation with the drawing refereed to. FIG. 4 shows a prior art for a charged particle beam adjusting method. Electron beam emitted from an electron gun 1 is collected by a condenser lens 2, and focused to a specimen 6 by an objective lens 5. The electron beam is raster scanned on the specimen 6 by deflectors 3 and 4, and a defect detection or a pattern size measurement are done.

Around the optical axis the electron can be focused finely, however at the deflection field edge 7, the beam diameter become large, because of aberrations. Though a dynamic focus lens 10 and a dynamic stigmatic lens, which is not shown, correct a field curvature and an astigmatism aberrations, the beam diameter is still large as shown 14. On the contrary, around the optical axis the beam diameter is small as shown 43, because of small aberrations.

If the electron beam with above mentioned deflection characteristics is raster scanned on the specimen, at the deflection edge a pixel size 12 and the beam size 14 are matched each other, however around the optical axis the pixel size 15 and the beam size are not matched each other. For example if the defect detection were done using these electron beam, the defects which are between raster and around the optical axis may not be detected.

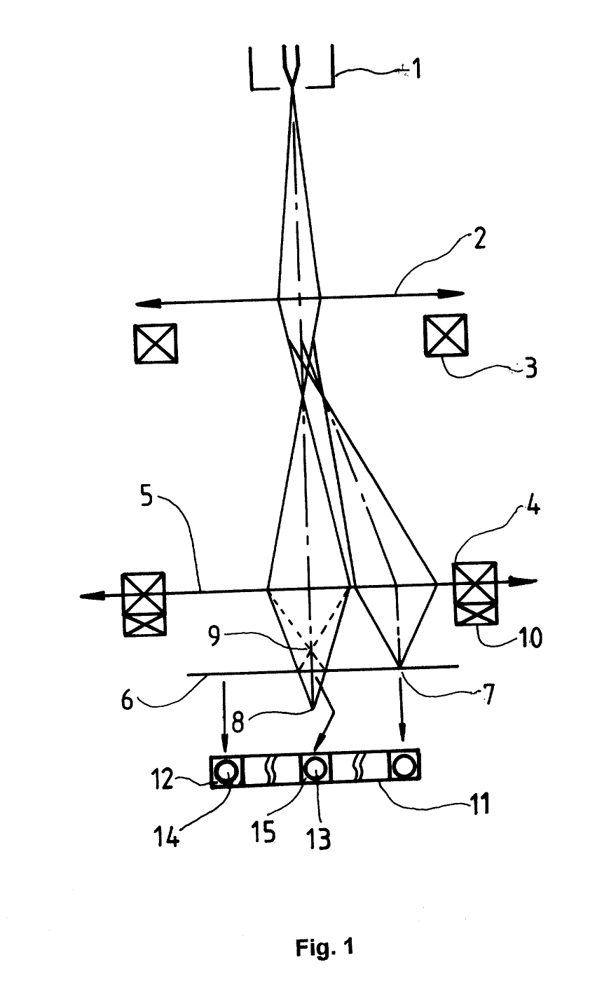

To improve above mentioned problem, the first embodiment of this invention is explained using the FIG. 1 The beam size at the deflection edge have a minimum value and it is impossible to obtain the same size as that at the optical axis On the contrary, it is possible to keep the beam diameter around the optical axis large value as that at the deflection edge.

In FIG. 1, the electron beam emitted from the electron gun 1 is collected by condenser lens 2 and focused to the specimen 6 by the objective lens 5. The electron beam is raster scanned on the specimen by the deflector 3 and 4, and the defect detection or the pattern size measurement is done.

When the electron beam is deflected to the place where is far from the optical axis, the field curvature are corrected by the dynamic focus lens 10, and when the electron beam is scanned to the place where is near the optical axis, the beam diameter is adjusted to the size which is match to the raster size.

The dynamic focus lens condition which minimize the beam diameter at the deflection edge is searched and the beam diameter is memorized. When the scan position is not the deflection edge, if the dynamic focus lens is adjusted to just focus condition for the place, the beam diameter become too small to be mach to the raster size, then the dynamic focus lens condition is adjusted to the out of focus condition so that the beam diameter is nearly equal to above memorized value. If we select a just focus plane as a near side plane to the objective lens as shown 9, then the dynamic focus lens condition must be changed largely. Therefore, we select a just focus plane as a far lens side as shown 8, that is an under focus condition.

For the pattern size measurement apparatus the following procedure is done. The dynamic focus lens is adjusted so that the beam diameter is minimum at the maximum deflection, and for the other deflection position, the dynamic focus lens is adjusted so that the beam diameter is nearly equal to the above minimum value at the maximum deflection. Using these nearly equal beam diameter the patterns are scanned and the secondary electron signal from the patterns are detected and from the secondary electron signal the pattern size is obtained. The scanning is done by the constant sized beam everywhere in the deflection field, as a results an accurate pattern size measurement can be obtained.

For the defect detection apparatus, the following procedure is done. The dynamic focus lens is adjusted so that at the maximum deflection position the beam diameter is minimum and the beam diameter is memorized. For the other deflection position the dynamic focus lens is adjusted so that the beam diameter is nearly equal to the memorized value. Keeping the beam diameter constant and equal to raster pitch, the specimen are scanned and the SE signal is detected. The defect is detected from this SE signal. Because the raster pitch and the beam diameter is nearly equal everywhere in the deflection position and in the specimen, all the specimen surface are scanned by the electron beam without opening, then the probability for missing defect is small and the current density is constant everywhere the deflection position and then the probability for detect false defect is also small.

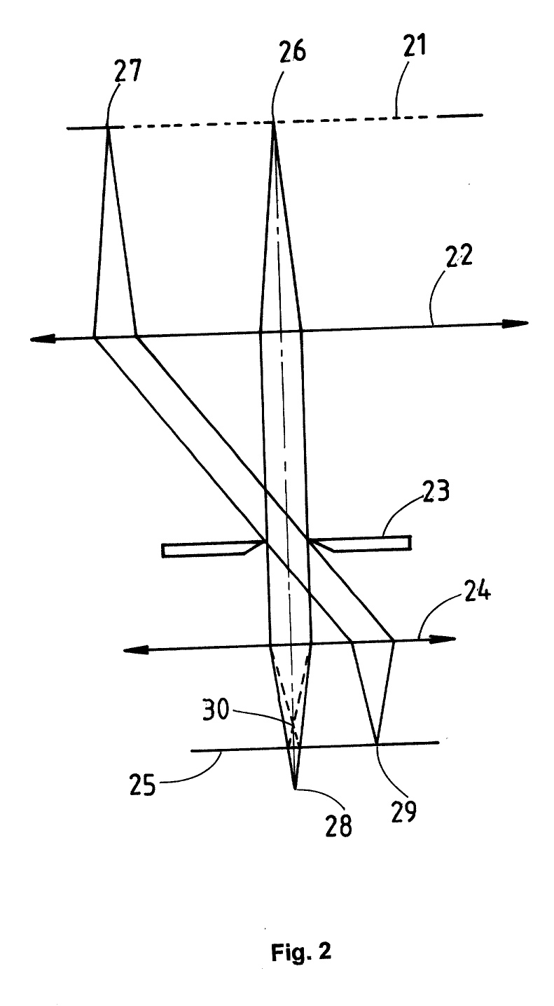

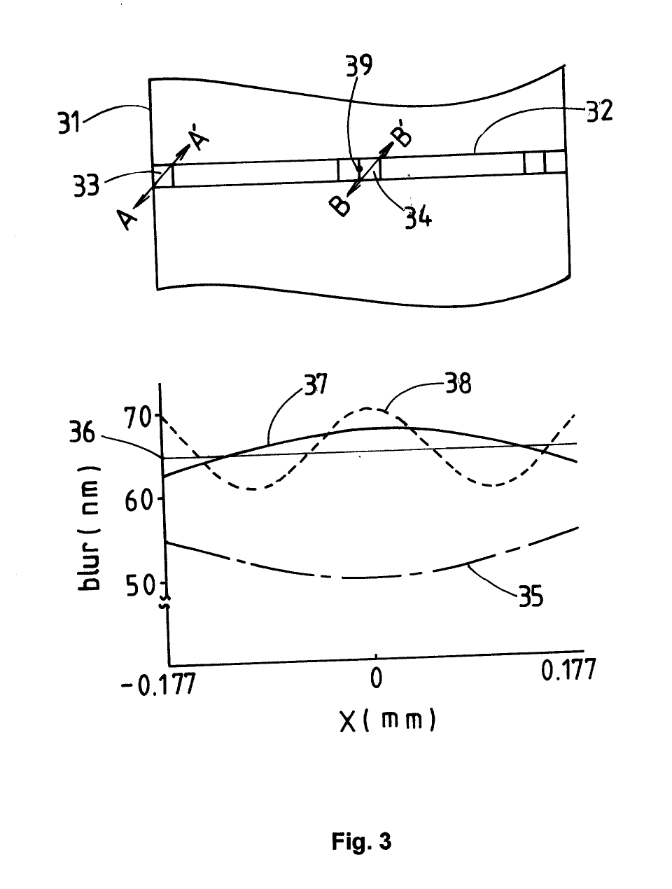

FIGS. 2 and 3 are the second embodiment of this invention. FIG. 3 shows an electron beam pattern projection method. Pattern area is divided into plural stripes 31, each stripe is divided into plural main fields 32, each main field is subdivided into sub fields, and pattern transfer is done sub field by sub field.

In the prior art, the dynamic focus lens is adjusted so that the maximum beam blur in each sub field become minimum, and each sub field is transferred with their dynamic focus lens condition. As a results, dose profile for the sub field 34 where is near the optical axis 39 is steep, because the beam blur is small. On the contrary the dose profile for the sub field 33 where is far from the optical axis has a gentle slope, because the beam blur is large. Therefore, especially when the pattern transfer is done using mask bias, the threshold level for the resist development is shifted from 50% to a little lower level for example, and then the developed line width at the smaller beam blur is smaller than that at larger beam blur place.

In this invention the following procedure is done. In FIG. 2, patterned electron beam through the mask 21 is focused to sensitive substrate 25 by two stage lenses 22 and 24. The patterned electron beam which is far from the optical axis is just focused to the substrate 29. On the contrary, the patterned electron beam is just focused not to the substrate 29 but to a little different place 28 or 30, then at the substrate plane 29 there is some beam blur. At the sub field where is far from the optical axis, there is no blur due to the out of focus, and there is beam blur due to the aberrations. On the contrary, in the sub field where is near the optical axis, as the aberration is small, total beam blur with small aberration and the out of focus must be nearly equal to the beam blur for the sub field where is far from the optical axis.

A concrete beam adjust method is explained using FIG. 3. For the sub field 33 where in the farthest from the optical axis in a main field 32 in the stripe 31, the beam blur as a function of diagonal position of the sub field is shown as dotted line curve 38. This means that aberration correction deflector and dynamic stigmator are adjusted so that at the center of this sub field the aberration is minimum and after this adjustment, the dynamic focus lens is adjusted so that the beam blur at the sub field center and the beam blur at the sub field edge are nearly equal each other. The maximum, the minimum and these are 70. 60 and 65 nm respectively in this case.

Next, for the sub field 34 that is near the optical axis, the lens adjusting method is shown. In the prior art as the beam blur at each sub field is minimized, the beam blur curve 35 as a function of diagonal position of the sub field has a minimum at the sub field center and maximum at the sub field edge. The minimum value is 50 nm and very small value. In this invention, from this lens condition when the lens excitation is decreased, the beam blur at the sub field center is increased and that at the sub field edge is decreased and at least become as curve 37. That is, the maximum and the minimum beam blur for the sub field near the optical axis are between the maximum and the minimum beam blur for the sub field of the main field edge. There is another method that the mean blur value between the maximum and the minimum blur for each sub field keep to the mean value between the maximum and the minimum blur for sub field of the main field edge.

For the other sub field in the main field, it is better to adjust the lens condition as a middle value between the lens condition for the sub fields of the optical axis and the main field edge. It is sufficient that the value of blur in each sub field are nearly equal each other, or that the beam blur maximum value and beam blur minimum value for each sub field are smaller than 70 nm and larger than 60 nm, where these values are the maximum and minimum values for the sub field at the main field edge, respectively. As a results, the beam blur difference in the main field is the improved from 20 nm to 10 nm, where the former value is the conventional method. Finally, the pattern size accuracy must be improved.

Above explanation does not consider the beam blur due to the space charge effect. To consider the space charge effect, the sub field which satisfy the main field edge and the maximum pattern density is selected, and for that selected sub field, the lens conditions that minimize the maximum beam blur with a beam current for the pattern density are searched. The lens conditions for the other sub field is also defined so that the maximum and minimum beam blur values are between the maximum and minimum value for above mentioned sub field, where the beam current matched to pattern density for each sub field must be flow. Plastically, only a minimum value of beam blur for arbitrary sub field must be adjusted to be larger than the minimum value for the main field edge and the maximum pattern density sub field, because the maximum beam blur condition may be satisfied naturally.

To obtain a certain beam blur, there are two method those are an under focus and an excess focus. In the former case the just focus plane is unti lens side from the sensitive substrate as shown 8 in FIG. 1, and in the latter case the just focus plane is the lens side from the sensitive substrate as shown 9 in FIG. 1. The former case is better, because the former case require smaller excitation change of the dynamic focus lens and for a selected case, the dynamic focus lens may not be necessary.

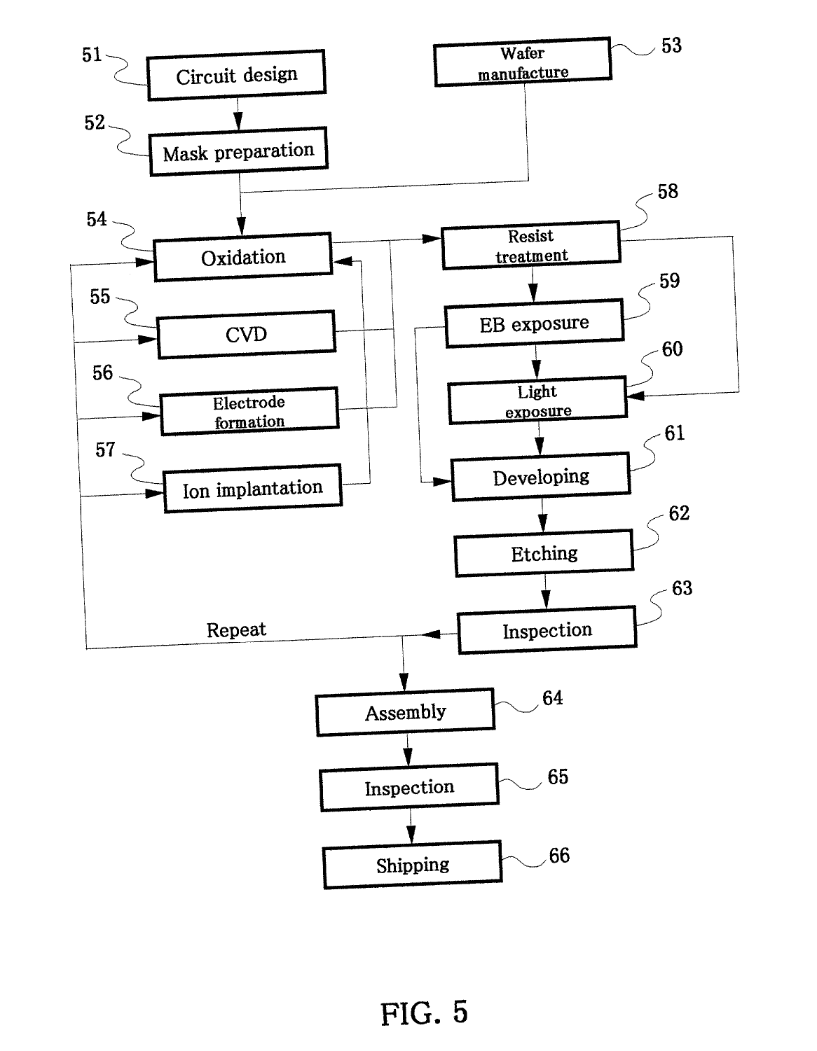

FIG. 5 is a flow chart of steps in a manufacturing a semiconductor device such as a semiconductor chip, a display panel, or CCD, for example. In step 51, the circuit for the device is designed. In step 52, reticles for the circuits are manufactured. In step 53, a wafer is manufactured from a material such as silicon.

Steps 54-63 are directed to wafer-processing steps, especially “pre-process” steps. In the pre-process steps, the circuit pattern defined on the reticle is transferred onto a wafer by microlithography. Step 64 is an assembly step in which the wafer that has been passed through steps 54-63 is formed into semiconductor chips. This step can include, e.g., assembling the devices and packaging. Step 65 is an inspection step in which any of various operability and qualification tests of the device produced in step 64 are conducted. Afterward, devices that successfully pass step 65 are finished, packaged, and shipped (step 66).

Steps 54-63 also provide representative details of wafer processing. Step 54 is an oxidation step for oxidizing the surface of a wafer. Step 55 involves chemical vapor deposition (CVD) for forming an insulating film on the wafer surface. Step 56 is an electrode-forming step for forming electrodes on the wafer. Step 57 is an ion-implantation step for implanting impurity into the wafer. Step 58 involves application of an exposure sensitive resist to the wafer. Step 59 involves exposing the resist by CPB microlithography, using the reticle produced in step 52, so as to imprint the resist with the reticle pattern, as described elsewhere herein. In step 60, a circuit pattern is exposed onto the wafer using optical microlithography. Although this figure shows both CPB and optical microlithography being performed, it alternatively is possible to transfer the entire pattern using only CPB microlithography. Step 61 involves developing the exposed resist on the wafer. Step 62 involves etching the wafer to remove material from areas where developed resist is absent. Step 63 involves wafer inspection process in which defect detection ets., are done. By repeating steps 54-63 such a numbers as required layer numbers, circuit patterns as defined by successive reticles are superposedly formed on the wafer and the semiconductor devices which act as designed characteristics are manufactured.

When the electron beam pattern projection method in this invention is used at above lithography process 3, the semiconductor device with fine pattern can be formed with good size accuracy and high yield production can be obtained. When the electron beam adjusting method in this invention is used at above inspection process, the semiconductor device can be formed with high yield.

Whereas the invention has been described in connection with multiple representative embodiment, it will be understood that the invention is not limited to such embodiments. On the contrary, the invention is intended to encompass all modifications, alternations, and equivalents as may be encompassed by the spirit and scope of the invention, as defined by the appended claims.

Having thus described the invention, what is claimed as new and desirable to be secured by Letters Patent is as follows:

1. A charged particle beam adjusting method comprising the steps of:
(a) a charged particle beam source, a deflector, an objective lens and a specimen are arranged so as to form a charged particle beam apparatus,
(b) lens conditions that a beam resolution is the best at the deflection field edge are searched,
(c) the beam resolution value is memorized,
(d) the lens conditions are defined so that everywhere in the deflection field the beam resolution is nearly equal to that memorized in (c).

2. The charged particle beam adjusting method of claim 1, wherein the charged particle beam apparatus is a pattern size measuring apparatus.

3. The charged particle beam adjusting method of claim 1, wherein the charged particle beam apparatus is a defect detection apparatus.

4. The charged particle beam adjusting method of claim 1, wherein the dynamic focus lens conditions are defined so that everywhere in the deflection field the beam current density is nearly equal.

5. A charged particle beam adjusting method for a charged particle beam apparatus comprising the steps of:
(a) a charged particle beam source, condenser lens, deflector, an objective lens and a specimen are arranged so as to form a charged particle beam apparatus,
(b) lens conditions that a beam diameter is minimum at the deflection field edge are searched,
(c) the beam diameter is memorized,
(d) the lens conditions are defined so that everywhere in the deflection field the beam diameter is nearly equal to that memorized in (c).

6. The charged particle beam adjusting method of claim 5, wherein the beam diameter is nearly equal to the raster pitch, everywhere in the scanning field.

7. The charged particle beam adjusting method of claim 5, wherein the charged particle beam apparatus is a pattern size measuring apparatus.

8. The charged particle beam adjusting method of claim 5, wherein the charged particle beam apparatus is a defect detection apparatus.

9. The charged particle beam adjusting method of claim 5, wherein the dynamic focus lens conditions are defined so that everywhere in the scanning field, the beam current density is nearly equal.

10. The charged particle beam adjusting method of claim 5, wherein;
a specimen is raster scanned and a secondary electron is detected.

11. A pattern transferring method comprises the step of:
(a) chip pattern are divided into plural main fields,
(b) each main field is divided into plural sub-fields,
(c) the minimum value for the maximum beam blur in the sub-field where is the sub-field in the main field edge, is searched through the dynamic focus lens varied, and the minimum value is memorized;
(d) the lens conditions for the other sub-fields are defined so that the maximum beam blur in each sub-field is equal to or larger than the said memorized beam blur in (c),
(e) the pattern transfer is done using the defined condition in (d), wherein the pattern transfer is done sub-field by sub-field.

12. The pattern transfer method of claim 11, wherein;
a pattern density is the maximum at said furthest sub field in the main field, and
the lens conditions for each sub field are defined on the beam current condition for the pattern density.

13. The pattern transfer method of claim 11, wherein;
the lens conditions for the sub field that the distance from the optical axis is not the maximum, are the nearer conditions to the lens conditions for the sub field in the main field edge, between two lens conditions which satisfy said condition in (e) of claim 11.

14. The pattern transfer method of claim 11, wherein;
the pattern size at the mask is designed a little smaller size than the desirable size, and wherein
said smaller size is the desirable size minus mask bias.

15. The charged particle beam adjusting method of claim 1, wherein the lens conditions for the arbitrary deflection position that the distance from the optical axis is not the maximum, are the nearer conditions to the lens conditions for the deflection edge, between two lens conditions which satisfy said condition in (d) of claim 1.

16. The device manufacturing method comprising the steps of;
(a) arranging substrates,
(b) forming patterns using the pattern transfer method of claim 11,
(c) detecting defects using a defect detecting apparatus.

17. The device manufacturing method comprising the steps of;
(a) arranging wafers,
(b) forming patterns using the pattern transfer method,
(c) the wafers are directed to wafer-processing steps,
(d) the wafers are evaluated at least after one of the wafer-processing steps by a apparatus which use the charged particle beam adjusting method of claim 1.

18. The device manufacturing method comprising the steps of;
(a) arranging wafers,
(b) forming patterns using the pattern transfer apparatus,
(c) the wafers are directed to wafer-processing steps,
(d) the wafers are evaluated at least after one of the wafer-processing steps by a apparatus which use the charged particle beam adjusting method of claim 5.

19. The device manufacturing method comprising the steps of;
(a) arranging substrates,
(b) forming patterns using the pattern transfer apparatus,
(c) detecting defects using a defect detecting method of claim 3.

20. The device manufacturing method comprising the steps of;
(a) arranging substrates,
(b) forming patterns using the pattern transfer apparatus,
(c) detecting defects using a defect detecting apparatus,
(d) measuring pattern size using a pattern size measuring method of claim 2.
